(19) United States
(12) Patent Application Publication
(10) Pub. No.: US 2004/0027792 A1
(43) Pub. Date: Feb. 12, 2004

(54) Intrinsically safe computer

(76) Inventor: Steven A. Newman, Maclean, VA (US)

Correspondence Address: JAMES J. RALABATE, 5792 MAIN STREET, WILLIAMSVILLE, NY, 14221, US

(21) Appl. No.: 10/601,902

(22) Filed: Jun. 23, 2003

Related U.S. Application Data
(63) Continuation-in-part of application No. 09/844,242, filed on Apr. 27, 2001.

(51) Int. Cl. H05K 5/00

(52) U.S. Cl. 361/679

(57) ABSTRACT

The invention is a enclosure which confers onto an enclosed computer or communication device the properties of instrinsic safety according to Class 1, Divisions 1, 2 or both of the U.S. Electrical Code, weatherproofing, or ruggedness. According to the system of the present invention, workers may make use of this system in environments in which typical electrical devices may not be used due to the presence of ambient ignitable gases and vapors or other environments which may cause damage to the electrical device.

### CROSS REFERENCES TO RELATED APPLICATIONS

This application is a Continuation in Part of U.S. patent application Ser. No. 09/844,242 filed Jun. 19, 2001 entitled “Intrinsically Safe Enclosure and Method.”

### INVENTION

The invention is directed to the field of enclosures for computers or communications devices which confers properties such as intrinsic safety, waterproofing, or otherwise made to be rugged to the enclosed devices.

### BACKGROUND OF THE INVENTION

The pervasiveness and efficiency of modem computers and communication devices have expanded their role from a desktop tool for document processing and application serving to a productivity enhancing tool for technical field workers to perform their job functions in a more efficient and comfortable manner. Their has been repeated affirmation in the marketplace of the gains in efficiency to be had from making computers mobile so that field workers can have the same access to information and computing power that traditional office workers have.

While mobile computer and communication systems have significantly enhanced productivity of mobile technical workers in fields such as manufacturing, inspection, data acquisition, remote sensing, and navigation, there are certain environments to which technicians are exposed which will not permit the desired use of ordinary computing and communications equipment due to the ambient conditions. These conditions include humidity, excessive heat, moisture, vibration, ambient flammable gases, gas vapors and liquids, radioactivity, and biological. Another concern is environments in which flammable, toxic, or volatile materials are present. Devices which can operate in these environments are known as Intrinsically Safe. According to the National Electric Code, 1990, Article 500, Class 1 environments, Flammable Gasses or Vapors, are locations in which flammable gases or vapors are or may be present in the air in quantities sufficient to produce explosive or ignitable mixtures. Class 1 is segmented into two divisions. A Class 1, Division 1 location is one in which ignitable concentrations of flammable gases or vapors may be present because: (1) they exist under normal operating conditions, (2) they exist frequently because of repair, maintenance operations, or leakage, (3) breakdown or faulty operation of equipment or process which causes simultaneous electrical equipment failure. A Class 1, Division 2 location is one in which ignitable concentrations of flammable liquids or gases may be present as a result of: (1) an accidental rupture or breakdown of the normally closed containers, systems, or equipment, (2) a failure or abnormal operation of the venting equipment, (3) being located adjacent to a Class 1, Division 1 location from which ignitable concentrations of gases or vapors might occasionally be communicated. Within Divisions 1 and 2 there are four groupings of ambient atmospheres segmented by the type of materials present: Group A is atmospheres containing acetylene, Group B is atmospheres containing hydrogen, fuel and combustible process gases containing more then 30 percent hydrogen by volume, or gases or vapors of equivalent hazard such as butadiene, ethylene oxide, propylene oxide, and acrolein, Group C is atmospheres such as cyclopropane, ethyl ether, ethylene, or gases or vapors of equivalent hazard, and Group D is atmospheres such as acetone, ammonia, benzene, butane, ethanol, gasoline, hexane, methanol, methane, natural gas, naptha, propane or gases or vapors of equivalent hazard. These environments are typical to the chemical, power, and petrochemical industries. Workers in these environments are prevented from making use of computer equipment that has not been rendered IS DIV 1 or DIV 2 due to the risk of explosion from spark generation. The above standards are examples of the type of intrinsic safety the enclosure may provide; however, and other current or future standards may be used as the standard of protection for the computer or communication device when inserted into the enclosure.

Typically, to effect intrinsic safety and/or ruggedization, devices are built from the component level up to be electrically insulated against sparking. This requires specialized components, limited production runs, re-engineering of existing products and significantly increases the cost of devices. Also, the latest technology advances is excluded from these devices. As a result, very few electronic items are built because manufactures and customers can not take advantage of the economies of scale derived from commercial-off-the-shelf (hereinafter COTS) products to meet ruggedization or IS needs.

Thus, there exists a need for a device that confers the properties of intrinsic safety and/or ruggedness to a computer or communication device but which requires little or no modification of an existing COTS computer/communications products or platforms.

### SUMMARY OF THE INVENTION

It is therefore an object of this invention to provide a novel enclosure for a computer or communication device which confers onto the enclosed device intrinsic safety or otherwise ruggedization but which is devoid of some or all of the aforementioned limitations.

It is another object of this invention to provide an enclosure with confers to a computer or communication device once inserted the property of intrinsically safety according to Article 500 of the National Electrical Code, Class 1, Divisions 1 and 2 or similar or future standards.

It is still another object of this invention to provide an enclosure which achieves intrinsic safety and/or ruggedness without significant modification of the enclosed general purpose computer/communication device.

Another object of the invention is to provide a method for imparting capabilities such as intrinsic saftey, ruggedization, weatherproofing, and the like to computing and communicating device which do not have such properties as manufactured or off the shelf.

These and additional objects of the present invention are accomplished generally by a ruggedized and/or intrinsically safe enclosed computer/communication system.

In a preferred embodiment of the present invention, a person using the computer/communication device will take the computer or communication device and insert it into the enclosure of the present invention rendering the computer system created by the combination of the two components intrinsically safe (IS), according to class 1, division 1, division 2 or both of the U.S. Electrical Code or other suitable future or current standards. The computer may be a desktop, laptop, pen tablet, wearable, PDA, or other type of computer and the communication device may be cell phone, or PDA, or other suitable communication device. The enclosure may alternatively afford benefits such as prevention from water and moisture, humidity, shock, dust, and other ambient conditions. Preferably the enclosure is designed to be hand held or supported on the body of a user such as on a belt which is worn around the waist torso, vest, or other suitable body part of the user. In the intrinsically safe embodiment, the person could operate the computer/communication device in an environment, such as a petrochemical refinery, where ambient volatile gases and vapors are present, without fear of spark or explosion caused by the computer. The enclosure may be sealed with the computer/communication device inside such that the end user cannot open the enclosure. Alternatively, the enclosure is hinged allowing the end user to remove and replace devices within the enclosure. In the hinged embodiment, when the user leaves the volatile environment and returns to a stable one, such as his residence or his office, he can simply remove the computer from the IS enclosure and access any data collected or to perform any other computer operations.

In another preferred embodiment of the present invention, the enclosure will provide the enclosed computer or communication device ruggedization according to MIL-STD-810F test procedures or other suitable future or current standards. The enclosure may additionally afford benefits such as prevention from water and moisture, humidity, shock, dust, and other ambient conditions.

In a still another preferred embodiment of the present invention, the enclosure will provide the enclosed computer or communication device both intrinsic safety, according to class 1, division 1, division 2 or both of the U.S. Electrical Code and ruggedization according to MIL-STD-810F test procedures. Alternatively, any similar current or future standards may be used as the basis for the rating of the enclosure.

In another related embodiment, the enclosure which mates with the computer or communication device is designed to be resistant to the elements, including humidity, dust, heat, and cold. Thus the computer or communication system created by the enclosure and the computer or communication device will allow a person to operate it in environments which would otherwise be detrimental or corrosive to the electrical elements of a computer or other such elements as could be damaged or caused to malfunction. The enclosure may be sealed with the computer/communication device inside such that the end user cannot open the enclosure. Alternatively, the enclosure is hinged allowing the end user to remove and replace devices within the enclosure. In the hinged embodiment, when the person returns from the field, the computer may be removed from the ruggedized enclosure for access of any data collected or to perform any other computer operations.

In yet another embodiment, the enclosure of the present invention may possess a wireless communication capability such that a user could be simultaneously or asynchronously transmitting data from his remote location. The antenna may be embedded in the enclosure or may protrude from the enclosure such that intrinsic safeness is not compromised by the wireless communication. Such communication can include wireless LAN (IEEE 802.11), cellular, Bluetooth, WLAN, satellite, or other suitable wireless protocol.

In still an additional embodiment the enclosure may possess an integral touch screen LCD or like display or other type of peripheral device such as a mouse, keypad, or microphone. In this manner the enclosure serves as an interface when mated with the computer. The user will insert the computer and a power supply into receiving bays which are accessed by an optional latching hinged door or other suitable securing mechanism. Alternatively, the enclosure may be sealed after the computer or communication device has been inserted into the enclosure, thus not allowing the end user to open the enclosure. A power button or other suitable activating mechanism including voice will allow the system to power on and off and touch screen technology including a touch screen keyboard will be used to activate the computer system. The presence of the integral display screen or any other device made integral to the enclosure will in no away affect the intrinsically safe, ruggedized properties, or other similar properties of the enclosure.

In each embodiment, the common inventive feature is that the IS and/or ruggedized properties of the system created from the mating of the computer and the enclosure are derived from the external case itself. Additionally, another common feature is that one or more of the functions of the computer or communications device which is protected by the enclosure are available to the user through the enclosure. As a result, standard COTS electrical components or devices may be used in the construction and/or in conjunction with the internal circuitry decreasing the cost and market acceptability of the product.

### BRIEF DESCRIPTION OF THE DRAWINGS

FIG. 1 illustrates a top view of the system of the present invention.

FIG. 2 illustrates a side view of the IS enclosure of the system of the present invention.

FIG. 3 illustrates a top view of the opened enclosure the present invention.

FIG. 4 illustrates a belt mounted embodiment of the present invention.

FIG. 5 illustrates an alternative belt mounted embodiment of the present invention.

FIG. 6 illustrates a single enclosure embodiment of the present invention.

FIG. 7 illustrates a vest embodiment of the present invention.

### DETAILED DESCRIPTION OF THE DISCLOSURE

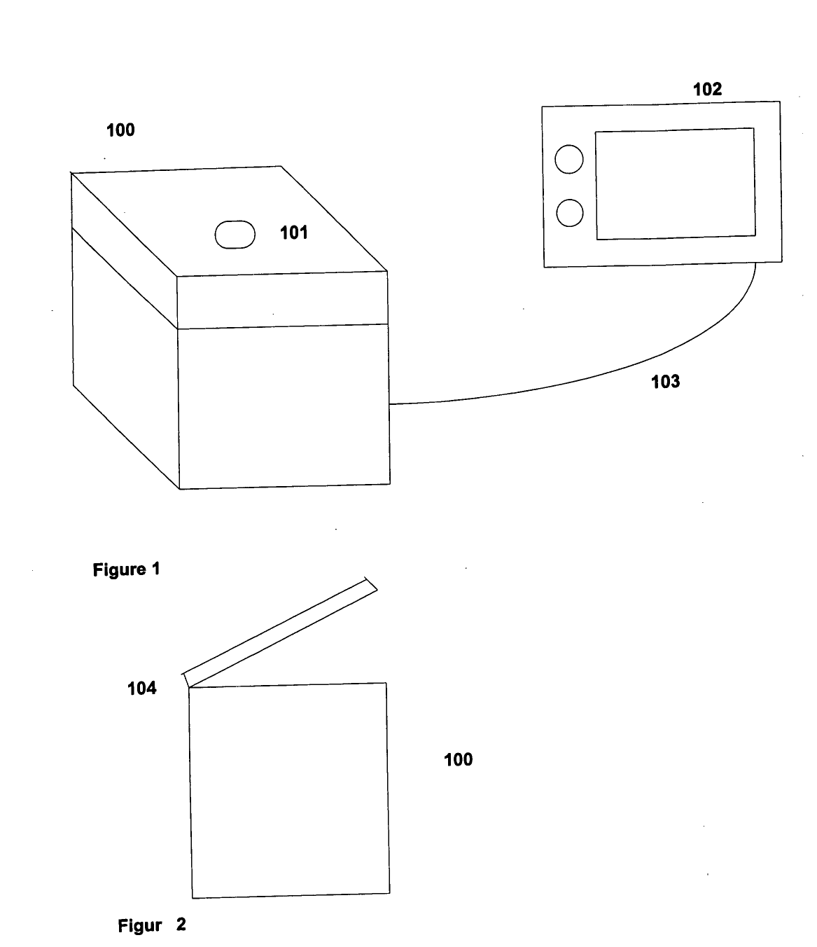

Discussion of the invention will now be made with specific reference to the drawing figures. FIG. 1 illustrates an exemplary embodiment of the present invention. The present invention includes an enclosure 100 with a latching lid which is released by latch release 101. The enclosure casing 100 is made of a light weight electrically insulating material such as plastic. The case 100 communicates with an external display 102 via hardwire connection 103. Alternatively, the connection between the case 100 and the display 102 is a wireless connection. The connection between the case 100 and the display 102 may be a permanent connection thus eliminating a contact point for a potential spark to be generated or alternatively the connection may be provided by an external safe connector. Connectors of this type are used in underwater communication line connections and are water and air tight. Utilized in the present invention such connectors would maintain the intrinsically safe properties of the enclosure casing 100. In this manner all electrical elements or devices within the enclosure case 100 are shielded from the ambient environments such that the presence of ignitable gases and/or vapors will not pose a risk of explosion to a person utilizing the computer inside the enclosure case 100 in such an environment. Alternatively, the connectors are weatherproof allowing the user to utilize the enclosed device in the elements. FIG. 2 illustrates a side view of the enclosure casing 100 which shows the lid of the casing open and hinged about hinge point 104. Alternatively, the enclosure may not have a hinge point, but is sealed after the device has been inserted into the enclosure.

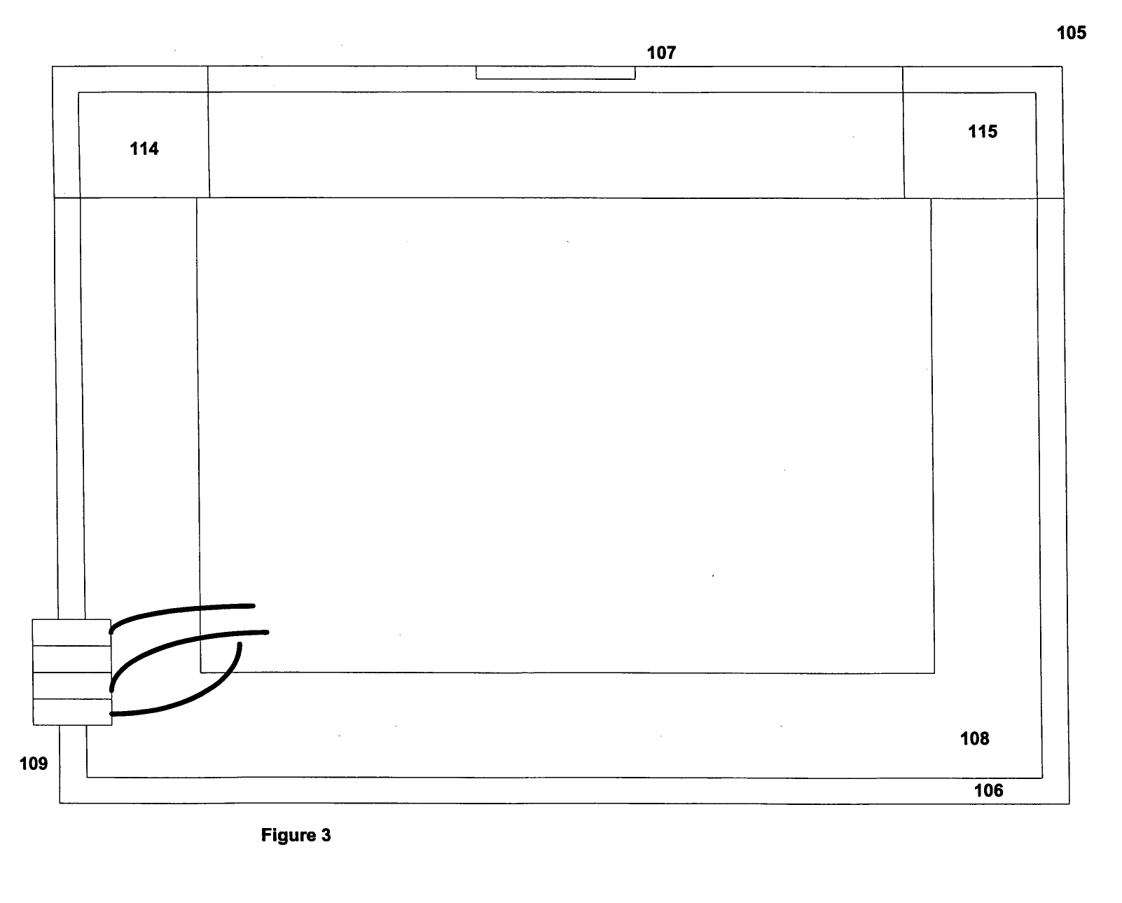

FIG. 3 illustrates a top view of the opened enclosure 105. The enclosure 105 contains a gasket or sealant 106 around the perimeter of the enclosure to provide a tight seal and water resistance to the interior of the enclosure when the lid to the enclosure is closed. The enclosure also has at least one hinge 107 from which the lid opens and closes. The interior of the enclosure is lined with a shock absorbing and insulating material 108 such as foam, silicone or rubber to provide the computer ruggedized property. The amount of such material may be customized to the level of protection the user's computer needs and may be added or removed to provide the computer a snug fit within the enclosure. The I/O 109 is an intrinsically safe interface which allows the user to attach peripherals to the enclosure. The interface may contain any of the following: USB, firewire, parallel, serial, power, display, custom, or future ports. The interior portion of the port interface contains individual connecters that plug into the computer's various ports. The cable for each connector may be flexible and coiled to allow each cable to extend to the computer interface. The individual connecters may also have a locking or securing mechanism to secure the connecter to the port on the computer. Additionally inside the enclosure may one ore more additional COTS devices such as a power supply 115, and optionally communications/wireless module 114 to permit wireless communication by the enclosure 100. Wireless communication can include wireless modem, wireless network, Bluetooth, or other wireless protocol. Alternatively, the power supply 115 may be external to the enclosure case 100 or a secondary power supply may interface with the enclosure. This secondary power supply may include an AC power source or a DC power source. Thus, when the computer is inserted into the enclosure 100 and the lid is shut and locked, a fully functional computer is created which has the property of being ruggedized and intrinsically safe. The external case itself will be made of a lightweight, durable low-loss dielectric and any ports or external interfaces will be appropriately shielded so as to eliminate the chance of spark and the possibility of environmental contamination to the internal components.

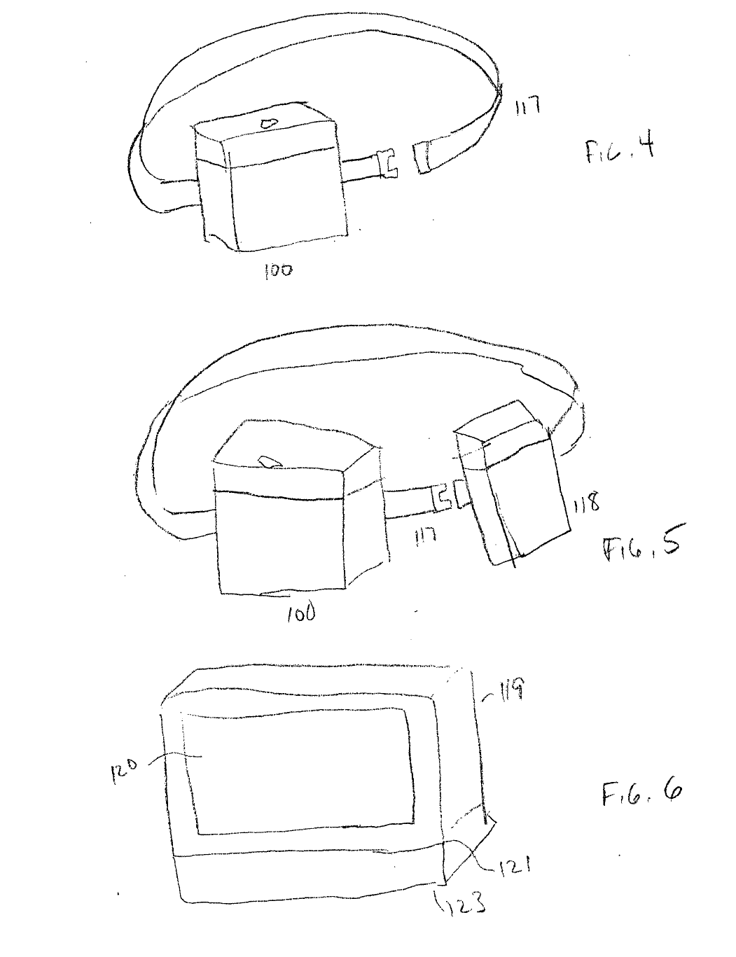

FIG. 4 illustrates the enclosure 100 attached to a belt 117 which is worn around the waist, torso, or other suitable body part of the user. In this manner the weight of the system can be distributed on the hips of the user minimizing the burden to the user. The belt is preferably adjustable so that it can accommodate persons of varying waist size. FIG. 5 illustrates a variation on the belt embodiment wherein an external power supply 118 is also secured on the belt 117 on the opposing side of the enclosure 100. A sealed cable will carry power from the power supply 118 to the enclosure 100, wherein the cable is concealed within the belt 117 or within a channel within the belt 117 and protected from electrical discharge and the ambient environment.

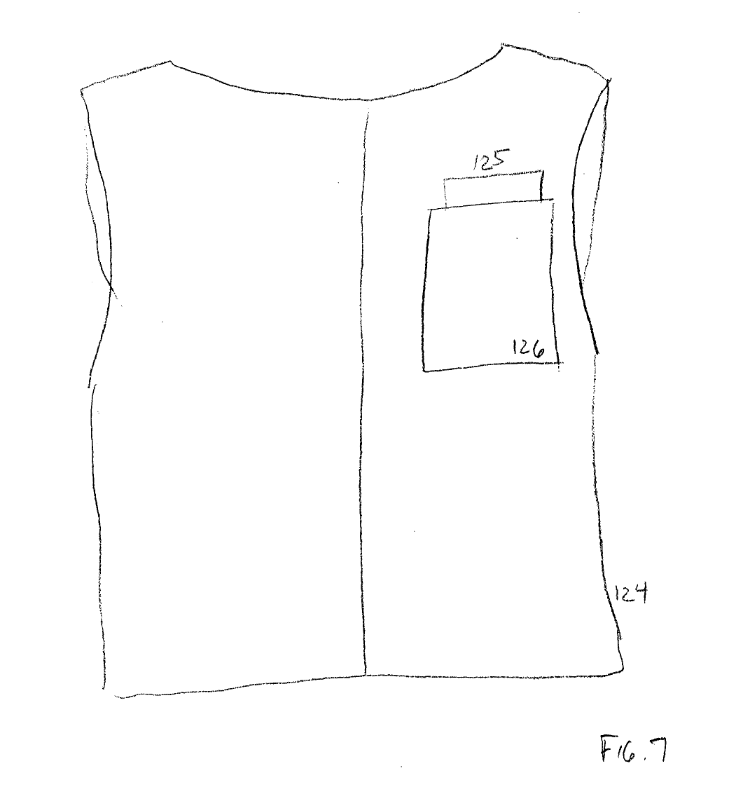

In another embodiment of the present invention, the intrinsically safe enclosure is not only receives the computer 105, but also has an integral touch screen display. See FIG. 6. In FIG. 6, the enclosure 119 has a display screen 120 on the front face. The display screen is electrically or wirelessly connected to the enclosed computer such that the computer output is displayed on the touch screen. Preferably the display screen 120 is responsive to touch or stylus input and makes use of a soft keyboard eliminating the need for external activation devices. Alternatively, the display screen has a microphone for speech input and activation. It has a hinge point 121 in the bottom so that a latching door 123 can open to reveal a compartment to receive the computer 105.

FIG. 7 illustrates a vest embodiment of the present invention. The vest 124 or other similar clothing such as a coat houses at least one computer or communications device 125 within an enclosure in a pocket 126 of the vest

The preferred and optimally preferred embodiments of the present invention have been described herein to illustrate the underlying principles of the invention, but it is to be understood that numerous modifications, designs, and alterations may be made without departing from the spirit and scope of this invention

I claim:

1) A system comprising:
an electronic device;
an enclosure which is enabled to receive and enclose said electronic device, said enclosure electrically connected to said electronic device;
wherein said enclosure confers to said electronic device properties including intrinsic safety, weatherproofing, or ruggedization.

2) The system of claim 1 wherein said electronic device is selected from the group consisting of a computer and communication device.

3) A method comprising the steps of:
inserting an electronic device into an enclosure;
connecting electrically said device and said enclosure;
sealing said enclosure around said device wherein said sealing enables said electronic device to have the properties of intrinsic safety, weatherproofing, or ruggedization.

4) A system for providing computer access to remote workers, the system comprising:
a computer module for providing processing means;
an enclosure for enclosing and electrically interconnecting with said module, wherein said enclosure is designed to be Intrinsically safe according to Class 1 Division 1, Division 2, or mixtures thereof of the U.S. Electrical Code;
a power supply for providing electrical power for electrical components in said module and said enclosure;
sealing means for selectively sealing the enclosure when said module has been interconnected with said enclosure.

5) The system of claim 4 wherein said enclosure comprises communication means.

6) The system of claim 4 wherein said enclosure has properties comprised of water tightness, non-corrosiveness, air tightness, shock resistance, and intrinsic safety.

7) The system of claim 5 wherein said enclosure has connection means for external devices, wherein said connection means does not reduce the efficacy of the properties of the enclosure.

8) The system of claim 4 wherein said communication means consists of wired communication means, wireless communication means, and mixtures thereof.

9) The system of claim 7 wherein said external devices comprise display devices, power supply devices, activation devices, sensor devices, transducer devices and communication devices.

10) The system of claim 4 wherein said computer is a wearable computer and further has securing means for securing said enclosure to the body of a wearer of the system.

11) A computer system for use in environments containing ambient flammable, combustible and explosive materials, the system comprising:
a computer module;
an enclosure which, when mated with said computer module enables said computer module as to be considered intrinsically safe according to class 1, division 1, division 2 or mixtures thereof of the U.S. Electrical Code;
a physical interconnection means for interconnecting said module and said enclosure;
an electrical interconnection means for interconnecting said module and said enclosure;
an access door on said enclosure for accessing at least one receiving bay;
a sealing means for sealing said door when it is closed;
a power supply to electrical components in said enclosure and said module;
a display screen integral to said enclosure, said display screen being responsive to touch or stylus input and said display screen capable of displaying a functional keyboard on said screen, said keyboard capable of affecting textual input.

12) The system of claim 11 wherein said enclosure comprises communication means.

13) The system of claim 11 wherein said enclosure has properties comprised of water tightness, non-corrosiveness, air tightness, shock resistance, and intrinsic safety.

14) The system of claim 11 wherein said enclosure has connection means for external devices, wherein said connection means does not reduce the efficacy of the properties of the enclosure.

15) The system of claim 11 wherein said communication means consists of wired communication means, wireless communication means, and mixtures thereof.

16) The system of claim 14 wherein said external devices comprise display devices, power supply devices, activation devices, sensor devices, transducer devices and communication devices.

17) The system of claim 11 wherein said display screen and enclosure have means to be activated both in a hands free and a manual manner.

18) The system of claim 11 wherein said system has both audio and visual means to power down and control said system.

19) The system of claim 11 wherein said enclosure has ports for connection of peripheral devices thereto.

20) A system for providing computer access to remote workers, the system comprising:
a computer module for providing processing means;
an enclosure for enclosing and electrically interconnecting with said module, wherein said enclosure has properties comprised of water tightness, non-corrosiveness, air tightness, or shock resistance;
a power supply for providing electrical power for electrical components in said module and said enclosure;
sealing means for selectively sealing the enclosure when said module has been interconnected with said enclosure.

21) The system of claim 20 wherein said enclosure comprises communication means.

22) The system of claim 20 wherein said enclosure has connection means for external devices, wherein said connection means does not reduce the efficacy of the properties of the enclosure.

23) The system of claim 20 wherein said communication means consists of wired communication means, wireless communication means, and mixtures thereof.

24) The system of claim 20 wherein said computer is a wearable computer and further has securing means for securing said enclosure to the body of a wearer of the system.

25) A system comprising:
a electronics module;
an enclosure for enclosing and electrically interconnecting with said module, wherein said enclosure has properties comprised of water tightness, non-corrosiveness, air tightness, intrinsic safety, or shock resistance;
a power supply for providing electrical power for electrical components in said module and said enclosure;
sealing means for selectively sealing the enclosure when said module has been interconnected with said enclosure.

26) The system of claim 25 wherein said electronics module comprises a computer.

27) The system of claim 25 wherein said electronics module comprises a communication device.
